(19) United States
(12) Patent Application Publication
(10) Pub. No.: US 2026/0101591 A1
(43) Pub. Date: Apr. 9, 2026

(54) ELECTROSTATIC DISCHARGE PROTECTION CIRCUIT

(71) Applicant: Vanguard International Semiconductor Corporation, Hsinchu (TW)

(72) Inventors: Li-Yang HONG, Taoyuan City (TW); Jian-Hsing LEE, Hsinchu City (TW); Yeh-Jen HUANG, Hsinchu City (TW); Yeh-Ning JOU, Hsinchu City (TW)

(73) Assignee: Vanguard International Semiconductor Corporation, Hsinchu (TW)

(21) Appl. No.: 18/907,262

(22) Filed: Oct. 4, 2024

(51) Int. Cl. H01L 27/02

(52) U.S. Cl. CPC H10D 89/811; H10D 89/911

(57) ABSTRACT

An electrostatic discharge protection circuit for protecting a core circuit is provided. The electrostatic discharge protection circuit includes a first high electron mobility transistor, a second high electron mobility transistor, a first resistor and a third high electron mobility transistor. The first high electron mobility transistor is coupled to a first input terminal. The second high electron mobility transistor is coupled between the first high electron mobility transistor and a second input terminal. The first resistor is coupled between the first input terminal and the core circuit. The third high electron mobility transistor is connected in parallel with the first resistor. A third gate of the third high electron mobility transistor is coupled to a first electrode of the third high electron mobility transistor.

### BACKGROUND OF THE INVENTION

### Field of the Invention

The present disclosure relates to an electronic circuit, and, in particular, it relates to an electrostatic discharge protection circuit.

### Description of the Related Art

Damage to electronic devices caused by electrostatic discharge (ESD) has become one of the biggest reliability issues for integrated circuit products today. As the size of integrated circuit products shrinks to deep sub-micron levels, the gate oxide layer of metal-oxide-semiconductor field-effect transistors is becoming thinner and thinner. Therefore, these integrated circuits are more susceptible to damage due to ESD.

In general, according to industry standards, the input and output pins (I/O pins) of an integrated circuit product must be able to pass ESD testing of both the human-body model (HBM) and the machine model (MM). The required voltage level for HBM ESD testing is more than 2000 volts, and the required voltage level for MM ESD testing is more than 200 volts. Therefore, ESD components in integrated circuit products need to be arranged close to all of the I/O pads to protect the internal core circuit from ESD currents.

### BRIEF SUMMARY OF THE INVENTION

An embodiment of the disclosure provides an electrostatic discharge protection circuit for protecting a core circuit. The electrostatic discharge protection circuit includes a first high electron mobility transistor, a second high electron mobility transistor, a first resistor and a third high electron mobility transistor. The first high electron mobility transistor is coupled to the first input terminal. The second high electron mobility transistor is coupled between the first high electron mobility transistor and a second input terminal. The first resistor is coupled between the first input terminal and the core circuit. The third high electron mobility transistor is connected in parallel with the first resistor. A third gate of the third high electron mobility transistor is coupled to the first electrode of the third high electron mobility transistor.

### BRIEF DESCRIPTION OF THE DRAWINGS

The present invention can be more fully understood by reading the subsequent detailed description and examples with references made to the accompanying drawings, wherein:

FIG. 1 is a schematic diagram of an operating system in accordance with some embodiments of the disclosure;

FIG. 2 is a schematic diagram of an operating system in accordance with some embodiments of the disclosure;

FIG. 3A is a schematic diagram of a high electron mobility transistor connected in parallel with a gate resistor in an operating system in accordance with some embodiments of the disclosure;

FIG. 3B is the equivalent circuit of FIG. 3A;

FIGS. 4A and 4B are schematic diagrams of operating systems in accordance with some embodiments of the disclosure;

FIGS. 5A and 5B are schematic diagrams of operating systems in accordance with some embodiments of the disclosure;

FIGS. 6A and 6B are schematic diagrams of operating systems in accordance with some embodiments of the disclosure; and

FIGS. 7A, 7B, 7C, and 7D are schematic diagrams of operating systems in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

In the gate drive circuit based on gallium nitride high electron mobility transistor (GaN HEMT), the gallium nitride high electron mobility transistor is required to connected to gate resistors having different resistances in ON state and OFF state to achieve optimized conditions of switching speed and electromagnetic interference (EMI) elimination. In conventional operating systems based on gallium nitride high electron mobility transistors, a chip including the gallium nitride high electron mobility transistor can only be externally connected to discrete passive components (for example, disposed on a printed circuit board). The discrete passive components cannot be integrated into the chip. Moreover, in the electrostatic discharge protection circuit of the gallium nitride high electron mobility transistor, a resistor having appropriate resistance is required to be connected in series with to the gate of the gallium nitride high electron mobility transistor in to limit the current flowing through the gate, thereby effectively achieving the effects of electrostatic discharge protection. However, the conventional electrostatic discharge protection circuit only has a single gate resistor, which cannot achieve the optimized conditions of switching speed and electromagnetic interference (EMI) elimination. Therefore, there is a need for an electrostatic discharge protection circuit for gallium nitride high electron mobility transistors to solve the above problems.

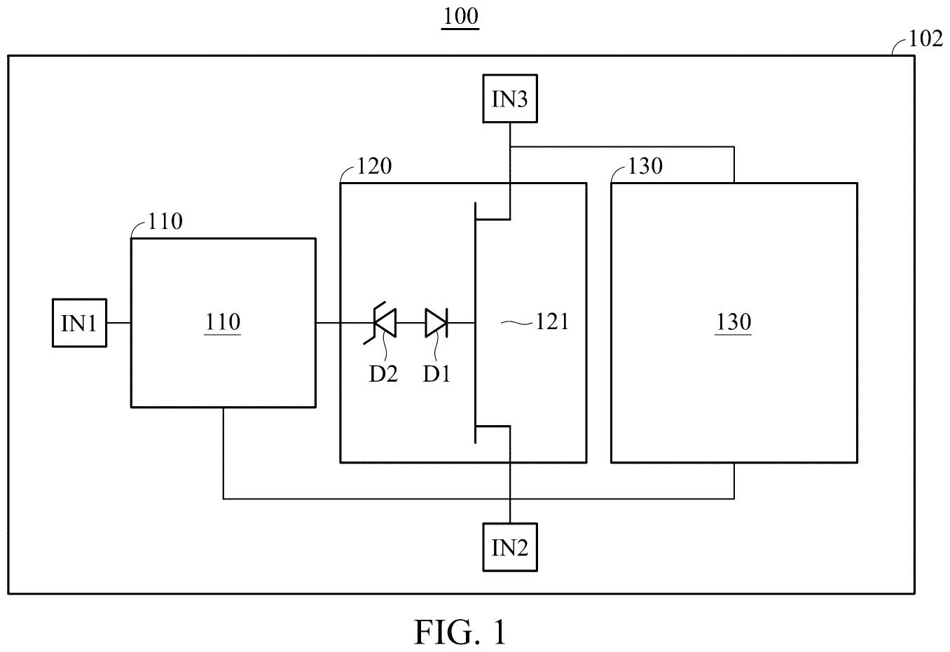

FIG. 1 is a schematic diagram of an operating system 100 in accordance with some embodiments of the disclosure. As shown in FIG. 1, the operating system 100 includes an electrostatic discharge protection circuit 110 (including electrostatic discharge protection circuits 200A, 200B, 200C, 300A, 300B, 400A, 400B, 500A, 500B, 500C, 500D shown in TT's the following figures), a core circuit 120 and a core circuit 130.

The operating system 100 is formed on a substrate 102. In some embodiments, for example, the substrate 102, such as a wafer, includes a Group III-V semiconductor material, such as gallium arsenide (GaAs), indium phosphide (InP), gallium nitride (GaN) or silicon germanium alloy (SiGe). In one embodiment, the substrate 102 is made of ceramic material, including silicon carbide, aluminum nitride (AIN), sapphire, metal inorganic materials, other suitable materials, or a combination thereof. In other embodiments, the substrate 102 may be a silicon on insulator (SOI) substrate. In other embodiments, the substrate 102 may also include a ceramic material and a pair of blocking layers (not shown) respectively provided on the upper and lower surfaces of the ceramic material. In some embodiments, the sapphire material may be aluminum oxide. In some embodiments, the blocking layers located on the upper and lower surfaces of the ceramic substrate may include single or multiple layers of insulating material and/or other suitable material layers, such as semiconductor layers. The insulating material layer may be oxide, nitride, oxynitride, or other suitable insulating materials. The semiconductor layer may be a silicon-containing material. In some embodiments, the substrate 102 is a Group III-V semiconductor material wafer, such as a gallium nitride wafer. In addition, the electrostatic discharge protection circuit 110, the core circuit 120 and the core circuit 130 are formed on the substrate 102 by Group III-V semiconductor material processes (such as gallium nitride processes).

The electrostatic discharge protection circuit 110 is coupled to the input terminal IN1, the input terminal IN2 and the core circuit 120. The electrostatic discharge protection circuit 110 is used to prevent electrostatic discharge current from entering the core circuit 120. For example, when an electrostatic discharge event occurs at the input terminal IN1 and the input terminal IN2 receives a ground voltage, the electrostatic discharge protection circuit 110 releases the electrostatic discharge current from the input terminal IN1 to the input terminal IN2. In some other embodiments, when an electrostatic discharge event occurs at the input terminal IN2 and the input terminal IN1 receives the ground voltage, the electrostatic discharge protection circuit 110 releases the electrostatic discharge current from the input terminal IN2 to the input terminal IN1.

The core circuit 120 is coupled to the input terminal IN2, the input terminal IN3 and the electrostatic discharge protection circuit 110. Furthermore, the core circuit 120 and the core circuit 130 are connected in parallel between the input terminal IN2 and the input terminal IN3. In some embodiments, the core circuit 120 also has the capability of releasing electrostatic discharge current to prevent electrostatic discharge current from the input terminal IN2 or the input terminal IN3 from entering the core circuit 130. For example, when an electrostatic discharge event occurs at the input terminal IN3 and the input terminal IN2 receives the ground voltage, the core circuit 120 releases the electrostatic discharge current from the input terminal IN3 to the input terminal IN2. In some other embodiments, when an electrostatic discharge event occurs at the input terminal IN2 and the input terminal IN3 receives the ground voltage, the core circuit 120 releases the electrostatic discharge current from the input terminal IN2 to the input terminal IN3.

The structure of core circuit 120 is not limited in the present disclosure. In some embodiments, the core circuit 120 includes a high electron mobility transistor (HEMT)-based gate driver circuit, such as a gallium nitride high electron mobility transistor (GaN HEMT)-based gate driver circuit.

In some embodiments, the core circuit 120 includes an enhancement-mode high electron mobility transistor (E-Mode HEMT) 121. The enhancement-mode high electron mobility transistor 121 is coupled to the input terminal IN2 and the input terminal IN3. The enhancement-mode high electron mobility transistor 121 and the core circuit 130 are connected in parallel. Furthermore, the drain of the enhancement-mode high electron mobility transistor 121 is coupled to the input terminal IN3. The source of the enhancement-mode high electron mobility transistor 121 is coupled to the input terminal IN2. The gate of the enhancement-mode high electron mobility transistor 121 is coupled to the electrostatic discharge protection circuit 110. As shown in FIG. 1, the enhancement-mode high electron mobility transistor 121 includes a diode D1 and a Schottky diode D2. The diode D1 and Schottky diode D2 are connected back to back. The cathode of the Schottky diode D2 is provided as the gate of the enhancement-mode high electron mobility transistor 121.

The core circuit 130 is coupled between the input terminal IN2 and the input terminal IN3. When an electrostatic discharge event occurs at the input terminal IN2 or IN3, the core circuit 120 releases the electrostatic discharge current, so that the core circuit 130 will not be damaged by the electrostatic discharge current. Since the core circuit 120 and the electrostatic discharge current protection circuit 110 have the capability of releasing electrostatic discharge current, the core circuit 120 may be integrated into the electrostatic discharge protection circuit 110.

The structures of core circuits 120 and 130 are not limited in the present disclosure. In some embodiments, when there is no electrostatic discharge event, the electrostatic discharge protection circuit 110 and the core circuit 120 stop working. At this time, the core circuit 130 works according to the signals or voltages of the input terminal IN2 and the input terminal IN3. For example, the core circuit 130 may receive a first operation voltage from the input terminal IN3 and receive a second operation voltage from the input terminal IN2.

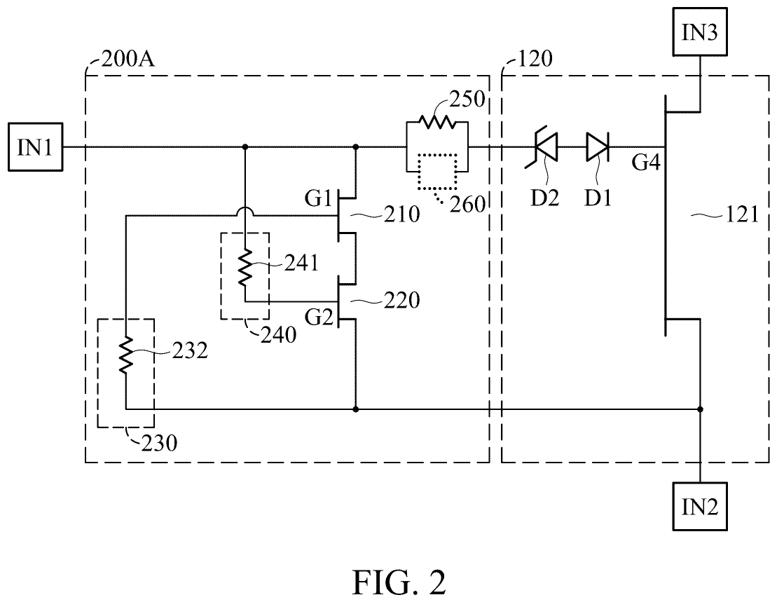

FIG. 2 is a schematic diagram of an electrostatic discharge protection circuit 200A in accordance with some embodiments of the disclosure. For brevity, the core circuit 130 is not shown in FIG. 2. The electrostatic discharge protection circuit 200A includes a high electron mobility transistor 210, a high electron mobility transistor 220, a current clamping circuit 230, a current clamping circuit 240, a resistor 250 and a high electron mobility transistor 260.

The high electron mobility transistor 210 is coupled to the input terminal IN1. The high electron mobility transistor 220 is coupled between the high electron mobility transistor 210 and the input terminal IN2. Each of the high electron mobility transistors 210 and 220 include a diode (similar to the diode D1) and a Schottky diode (similar to the Schottky diode D2). For brevity, the back-to-back diode pairs of high electron mobility transistors 210 and 220 are omitted.

The current clamping circuit 230 is coupled between the input terminal IN2 and the high electron mobility transistor 210 to clamp the current which enters the high electron mobility transistor 210 from the input terminal IN2. In some embodiments of the present disclosure, the current clamping circuit 230 includes a resistor 232. In this embodiment, the resistor 232 is directly connected between the gate G1 of the high electron mobility transistor 210 and the input terminal IN2. The resistor 232 reduces the current which enters the high electron mobility transistor 210 to ensure that the high electron mobility transistor 210 is completely turned off when there is no electrostatic discharge event.

The current clamping circuit 240 is coupled between the input terminal IN1 and the gate of the high electron mobility transistor 220. In some embodiments of the present disclosure, the current clamping circuit 240 includes a resistor 241. In this embodiment, the resistor 241 is directly connected between the input terminal IN1 and the gate G2 of the high electron mobility transistor 220 to reduce the current which enters the gate G2 of the high electron mobility transistor 220.

Since the current which enters the gates of the high electron mobility transistors 210 and 220 is limited by the resistors 232 and 241, this ensures that the high electron mobility transistors 210 and 220 are turned off when no electrostatic discharge event occurs.

The resistor 250 is coupled between the input terminal IN1 and the core circuit 120. In this embodiment, the resistor 250 is located close to the core circuit 120 to reduce the electrostatic discharge current which enters the core circuit 120. In some embodiments in which the core circuit 120 includes the enhancement-mode high electron mobility transistor 121, the resistor 250 is coupled to the gate G4 of the enhancement-mode high electron mobility transistor 121 and may serve as the gate resistor of the enhancement-mode high electron mobility transistor 121.

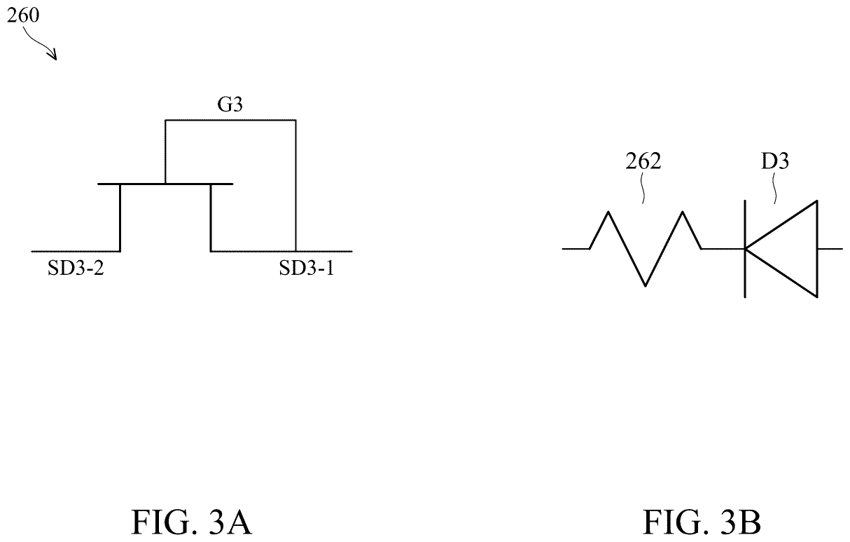

FIG. 3A is a schematic connection diagram of the high electron mobility transistor 260 connected in parallel with a gate resistor (the resistor 250) in an operating system in accordance with some embodiments of the disclosure. FIG. 3B is the equivalent circuit of FIG. 3A. As shown in FIGS. 2, 3A, and 3B, the gate resistor of the electrostatic discharge protection circuit 200A further includes the high electron mobility transistor 260. The high electron mobility transistor 260 is coupled between the input terminal IN1 and the core circuit 120. The high electron mobility transistor 260 and the resistor 250 are connected in parallel. Furthermore, the high electron mobility transistor 260 and the resistor 250 are connected in parallel between the gate G4 of the enhancement-mode high electron mobility transistor 121 and the input terminal IN1.

As shown in FIG. 3A, the high electron mobility transistor 260 has a gate G3, an electrode SD3-1 and an electrode SD3-2. In some embodiments, the gate G3 of the high electron mobility transistor 260 is coupled to the electrode SD3-1. Furthermore, the gate G3 of the high electron mobility transistor 260 is directly connected to the electrode SD3-1. Furthermore, the electrode SD3-2 of the high electron mobility transistor 260 is coupled to the input terminal IN1. In addition, the gate G3 and electrode SD3-1 of the high electron mobility transistor are coupled to the core circuit 120, for example, coupled to the gate G4 of the enhancement-mode high electron mobility the transistor 121, as shown in FIGS. 2 and 3A.

In some embodiments, when the electrode SD3-1 serves as the source of the high electron mobility transistor 260, the electrode SD3-2 serves as the drain of the high electron mobility transistor 260. Alternatively, when electrode SD3-1 serves as the drain of the high electron mobility transistor 260, the electrode SD3-2 serves as the source of the high electron mobility transistor 260.

As shown in FIGS. 3A and 3B, when the gate (the gate G3) of the high electron mobility transistor 260 is directly connected to the source or drain (the electrode SD3-1), the high electron mobility transistor 260 having this connection may also be called diode-connected transistor, and its equivalent circuit may be regarded as a diode D3 and a resistor 262 connected in series. The equivalent circuit shown in FIG. 3B has rectification characteristics similar to that of a diode, and the required resistance value may be obtained by adjusting the device width of the high electron mobility transistor 260. In some embodiments of the present invention, two ends of the resistor 262 of the equivalent circuit are respectively coupled to the input terminal IN1 and the cathode of the diode D3. Furthermore, the anode of the diode D3 of the equivalent circuit is coupled to the core circuit 120, for example, coupled to the gate G4 of the enhancement-mode high electron mobility transistor 121, as shown in FIGS. 2, 3A, and 3B.

When an electrostatic discharge event occurs at the input terminal IN1 and the input terminal IN2 receives a ground voltage, the gate voltage of the high electron mobility transistor 210 is gradually increased due to the capacitive coupling effect of the parasitic capacitor between the drain and gate of the high electron mobility transistor 210. When the gate voltage of the high electron mobility transistor 210 reaches a target value, the high electron mobility transistor 210 is turned on. At this time, since the resistor 241 is coupled between the input terminal IN1 and the high electron mobility transistor 220, the high electron mobility transistor 220 is turned on. Therefore, an electrostatic discharge current is released to the input terminal IN2 from the input terminal IN1 through the high electron mobility transistors 210 and 220.

Moreover, when an electrostatic discharge event occurs at the input terminal IN1 and the input terminal IN2 receives a ground voltage, the high electron mobility transistor 260 is turned off (the input terminal IN1 will apply a reverse bias to the high electron mobility transistor 260, so that the diode D3 in the equivalent circuit of FIG. 3B is turned off). At this time, the voltage of the gate G4 of the enhancement-mode high electron mobility transistor 121 will be clamped to a predetermined value by the resistor 250 to block the electrostatic discharge current enters the enhancement-mode high electron mobility transistor 121, so the enhancement-mode high electron mobility transistor 121 will not be damaged by the electrostatic discharge current.

Similarly, when an electrostatic discharge event occurs at the input terminal IN2 and the input terminal IN1 receives a ground voltage, the gate voltage of the high electron mobility transistor 220 is gradually increased the capacitive coupling effect of the parasitic capacitor between the drain and the gate of the high electron mobility transistor 220. When the gate voltage of the high electron mobility transistor 220 reaches the target value, the high electron mobility transistor 220 is turned on. Since the resistor 232 is coupled between the input terminal IN2 and the high electron mobility transistor 210, the high electron mobility transistor 210 is turned on. Therefore, an electrostatic discharge current is released to the input terminal IN1 from the input terminal IN2 through the high electron mobility transistors 220 and 210.

Since an electrostatic discharge current is released to the input terminal IN1 or IN2 through the high electron mobility transistors 210 and 220, this ensures that the core circuit 120 will not be damaged by the electrostatic discharge current. When there is no electrostatic discharge event, the input terminal IN1 may receive the first predetermined voltage, and the input terminal IN2 may receive the second predetermined voltage. When the second predetermined voltage is higher than the first predetermined voltage, the resistor 232 blocks the current from the input terminal IN2. Therefore, it is ensured the high electron mobility transistor 210 is turned off. When the first predetermined voltage is higher than the second predetermined voltage, the resistor 241 reduces the current which enters the high electron mobility transistor 220. Therefore, it is also ensured the high electron mobility transistor 220 is turned off.

In addition, when an electrostatic discharge event occurs at the input terminal IN3 and the input terminal IN2 receives a ground voltage, the enhancement-mode high electron mobility transistor 121 in the core circuit 120 releases the electrostatic discharge current to the input terminal IN2 from the input terminal IN3. Similarly, when an electrostatic discharge event occurs at the input terminal IN2 and the input terminal IN3 receives as ground voltage, the enhancement-mode high electron mobility transistor 121 releases the electrostatic discharge current to the input terminal IN3 from the input terminal IN2. Since the electrostatic discharge current does not flow into the gate G4 of the enhancement-mode high electron mobility transistor 121, this ensures that the gate G4 of the enhancement-mode high electron mobility transistor 121 will not be damaged by the electrostatic discharge current.

However, when the core circuits 120 and 130 in the operating system 100 (FIG. 1) are in normal operation (i.e., no electrostatic discharge event occurs), the electrostatic discharge circuit 110 (FIG. 1) is operated in normal mode. In normal mode, the high electron mobility transistor 210 or the high electron mobility transistor 220 is turned off to reduce leakage current.

In some embodiments of the present invention, through the resistor 250 and the high electron mobility transistor 260 connected in parallel between the input terminal IN1 and the gate G4 of the enhancement-mode high electron mobility transistor 121, the enhancement-mode high electron mobility transistor 121 of the core circuit 120 may be connected to the gate resistors having different resistance values in ON or OFF states to achieve the optimized conditions of switching speed and electromagnetic interference (EMI) elimination.

For example, when no electrostatic discharge event has occurred and the enhancement-mode high electron mobility transistor 121 is turned on, the high electron mobility transistor 260 is turned off. Specifically, when the voltage difference between the gate G4 (coupled to the input terminal IN1) and the source (coupled to the input terminal IN2) of the enhancement-mode high electron mobility transistor 121 is greater than the threshold voltage of the enhancement-mode high electron mobility transistor 121 (the enhancement-mode high electron mobility transistor 121 is turned on), the input terminal IN1 will apply a reverse bias to the high electron mobility transistor 260, causing the diode D3 in the equivalent circuit of FIG. 3B to be turned off. Therefore, the current from the input terminal IN1 only flows through the resistor 250 (and does not flow through the diode-connected high electron mobility transistor 260) and enters the enhancement-mode high electron mobility transistor 121.

For example, when no electrostatic discharge event has occurred and the enhancement-mode high electron mobility transistor 121 is turned off, the high electron mobility transistor 260 is turned on. Specifically, when the voltage difference between the gate G4 (coupled to the input terminal IN1) and the source (coupled to the input terminal IN2) of the enhancement-mode high electron mobility transistor 121 is less than the threshold voltage of the enhancement-mode high electron mobility transistor 121 (the enhancement-mode high electron mobility transistor 121 is turned off), the input terminal IN2 will apply a forward bias to the high electron mobility transistor 260, causing the diode D3 in the equivalent circuit of FIG. 3B to be turned on. At this time, the gate resistance of the enhancement-mode high electron mobility transistor 121 is the equivalent resistance of the resistor 250 and the resistor 262 (FIG. 3B) in parallel connection. Therefore, relative to the resistance value of the enhancement-mode high electron mobility transistor 121 in ON state, the enhancement-mode high electron mobility transistor 121 has a smaller resistance value in OFF state. In some embodiments of the present invention, the required equivalent resistance value may be obtained by adjusting the channel width of the high electron mobility transistor 260 to increase the turn-off speed of the enhancement-mode high electron mobility transistor 121.

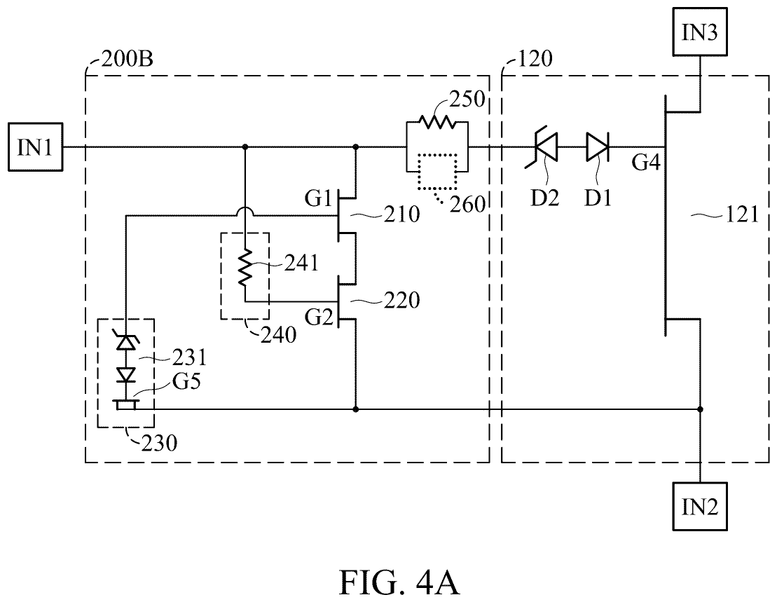

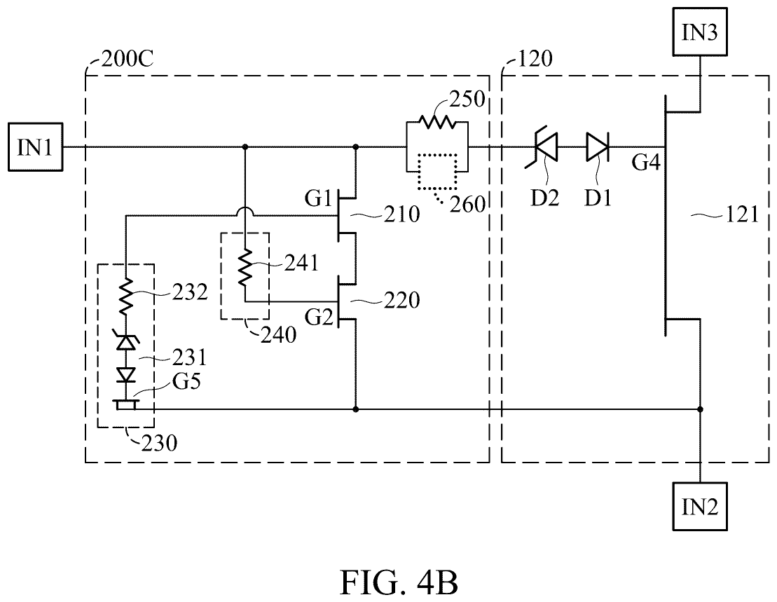

Next, various embodiments of the current clamping circuit of the electrostatic discharge protection circuit will be described with reference to FIGS. 4A, 4B, 5A, 5B, 6A, 6B, and 7A to 7D.

FIG. 4A is a schematic diagram of an electrostatic discharge protection circuit 200B in accordance with some embodiments of the disclosure. The differences in FIGS. 2 and 4A is at least that the current clamping circuit 230 in FIG. 4A includes a high electron mobility transistor 231. The drain and source of the high electron mobility transistor 231 are directly connected to the input terminal IN2. A gate G5 of the high electron mobility transistor 231 is directly connected to the gate G1 of the high electron mobility transistor 210. In some embodiments, the size of high electron mobility transistor 231 is smaller than the size of high electron mobility transistor 210 or 220. In this embodiment, the high electron mobility transistors 210 and 220 have similar sizes.

As shown in FIG. 4A, the high electron mobility transistor 231 has a back-to-back diode pair. The back-to-back diode pair of the high electron mobility transistor 231 may block the current from the input terminal IN2 from entering the high electron mobility transistor 210 and ensures that the high electron mobility transistor 210 is turned off when there is no electrostatic discharge event, thereby reducing the leakage current of the electrostatic discharge protection circuit 200B.

FIG. 4B is a schematic diagram of an electrostatic discharge protection circuit 200C in accordance with some embodiments of the disclosure. FIG. 4B is similar to FIG. 4A, except that the current clamping circuit 230 includes an additional resistor 232. In this embodiment, the resistor 232 is coupled between the gate G5 of the high electron mobility transistor 231 and the gate G1 of the high electron mobility transistor 210. The resistor 232 may reduce the current which enters the high electron mobility transistor 210 to ensure that the high electron mobility transistor 210 is completely turned off when there is no electrostatic discharge event.

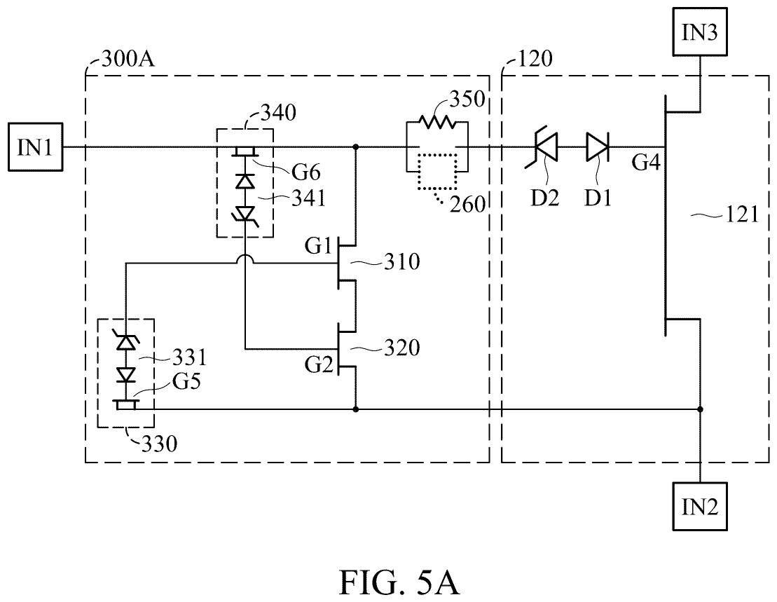

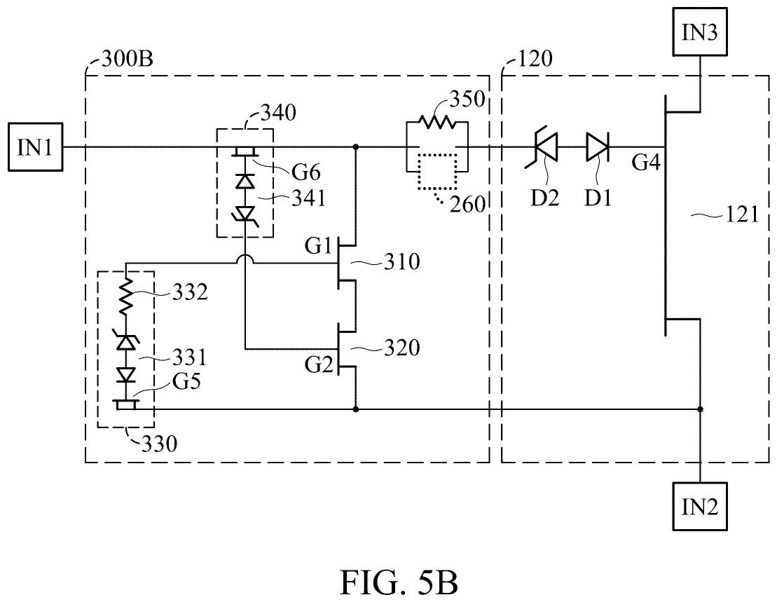

FIG. 5A is a schematic diagram of an electrostatic discharge protection circuit 300A in accordance with some embodiments of the disclosure. In this embodiment, the electrostatic discharge protection circuit 300A includes high electron mobility transistors 310 and 320, current clamping circuits 330 and 340, a resistor 350 and the high electron mobility transistor 260. The high electron mobility transistor 310 and the high electron mobility transistor 320 are connected in series between the input terminal IN1 and the input terminal IN2. The resistor 350 and the high electron mobility transistor 260 are connected in parallel between the input terminal IN1 and the core circuit 120. Since the characteristics of the high electron mobility transistors 310 and 320 are similar to those of the high electron mobility transistors 210 and 220 in FIG. 2, the related description is omitted here. Since the characteristics of the resistor 350 are similar to the characteristics of the resistor 250 in FIG. 2, the related description is omitted here. In addition, the connection, equivalent circuit and characteristics of the high electron mobility transistor 260 can be referred to the foregoing description, the related description is omitted here.

The current clamping circuit 330 is coupled between the gate G1 of the high electron mobility transistor 310 and the input terminal IN2, and includes a high electron mobility transistor 331. Since the characteristics of the high electron mobility transistor 331 are similar to the characteristics of the high electron mobility transistor 231 in FIG. 4A, the related description is omitted here.

The current clamping circuit 340 is coupled between the input terminal IN1 and the gate G2 of the high electron mobility transistor 320. In this embodiment, the current clamping circuit 340 includes a high electron mobility transistor 341. The drain and source of the high electron mobility transistor 341 are coupled to the input terminal IN1. A gate G6 of the high electron mobility transistor 341 is coupled to the gate G2 of the high electron mobility transistor 320.

As shown in FIG. 5A, the high electron mobility transistor 341 has a back-to-back diode pair. The back-to-back diode pairs of the high electron mobility transistor 341 may block the current from the input terminal IN1 from entering the gate G2 of the high electron mobility transistor 320, this ensures that the high electron mobility transistor 320 is turned off when there is no electrostatic discharge events, thereby reducing the leakage current of the electrostatic discharge protection circuit 300A.

When an electrostatic discharge event occurs at the input terminal IN1 and the input terminal IN2 receives a ground voltage, the gate voltage of the high electron mobility transistor 310 is gradually increased due to the capacitive coupling effect of the parasitic capacitor between the drain and the gate G1 of the high electron mobility transistor 310. When the gate voltage of the high electron mobility transistor 310 reaches a first target value, the high electron mobility transistor 310 is turned on. At this time, since the electrostatic discharge event turns on the high electron mobility transistor 341, the gate voltage of the high electron mobility transistor 320 is increased. When the gate voltage of the high electron mobility transistor 320 reaches a second target value, the high electron mobility transistor 320 is turned on. Therefore, the electrostatic discharge current is released to the input terminal IN2 from the input terminal IN1 through the high electron mobility transistors 310 and 320.

Similarly, when an electrostatic discharge event occurs at the input terminal IN2 and the input terminal IN1 receives a ground voltage, the gate voltage of the rate transistor 320 is gradually increased due to the capacitive coupling effect of the parasitic capacitor between the drain and the gate G2 of the high electron mobility transistor 320. When the gate voltage of the high electron mobility transistor 320 reaches a third target value, the high electron mobility transistor 320 is turned on. At this time, since the electrostatic discharge event turns on the high electron mobility transistor 331, the gate voltage of the high electron mobility transistor 310 is increased. When the gate voltage of the high electron mobility transistor 310 reaches a fourth target value, the high electron mobility transistor 310 is turned on. Therefore, the electrostatic discharge current is released to the input terminal IN1 from the input terminal IN2 through the high electron mobility transistors 320 and 310.

Since the electrostatic discharge current enters the input terminal IN1 or the input terminal IN2 through the high electron mobility transistor 310 and the high electron mobility transistor 320, this ensures that the core circuit 120 will not be damaged by the electrostatic discharge current. When there is no electrostatic discharge event, the input terminal IN1 may receive the first predetermined voltage, and the input terminal IN2 may receive the second predetermined voltage. When the second predetermined voltage is higher than the first predetermined voltage, the back-to-back diode pair of the high electron mobility transistor 331 blocks the current from the input terminal IN2, this ensures that the high electron mobility transistor 310 is turned off. When the first predetermined voltage is higher than the second predetermined voltage, the back-to-back diode pair of the high electron mobility transistor 341 blocks the current from the input terminal IN1, this ensures that the high electron mobility transistor 320 is turned off.

In normal operation (i.e., no electrostatic discharge event occurs), since the high electron mobility transistors 331 and 341 block current from entering the high electron mobility transistors 320 and 310, no leakage current passes through the high electron mobility transistors 320 and 310 to reduce the power consumption of the electrostatic discharge protection circuit 300A. In some embodiments, the size of the high electron mobility transistors 331 and 341 is smaller than the size of the high electron mobility transistors 310 or 320. In this example, the size of the high electron mobility transistor 331 is similar to the size of the high electron mobility transistor 341. In addition, the size of the high electron mobility transistor 310 is similar to the size of the high electron mobility transistor 320.

When the electrostatic discharge event does not occur and the enhancement-mode high electron mobility transistor 121 is turned on, the high electron mobility transistor 260 is turned off. At this time, the gate resistance of the enhancement-mode high electron mobility transistor 121 in ON state is the equivalent resistance of the resistor 350 only. For example, when no electrostatic discharge event has occurred and the enhancement-mode high electron mobility transistor 121 is turned off, the high electron mobility transistor 260 is turned on. At this time, the gate resistance of the enhancement-mode high electron mobility transistor 121 is the equivalent resistance of the resistor 350 and the resistor 262 (FIG. 3B) in parallel connection. Therefore, relative to the resistance value of the enhancement-mode high electron mobility transistor 121 in ON state, the enhancement-mode high electron mobility transistor 121 has a smaller resistance value in OFF state.

FIG. 5B is a schematic diagram of an electrostatic discharge protection circuit 300B in accordance with some embodiments of the disclosure. FIG. 5B is similar to FIG. 5A, except that the current clamping circuit 330 includes an additional resistor 332. In this embodiment, the resistor 332 is coupled between the gate G5 of the high electron mobility transistor 331 and the gate G1 of the high electron mobility transistor 310. The resistor 332 is used to reduce the high electron mobility transistor 310, this ensures that the high electron mobility transistor 310 is completely turned off when there is no electrostatic discharge event.

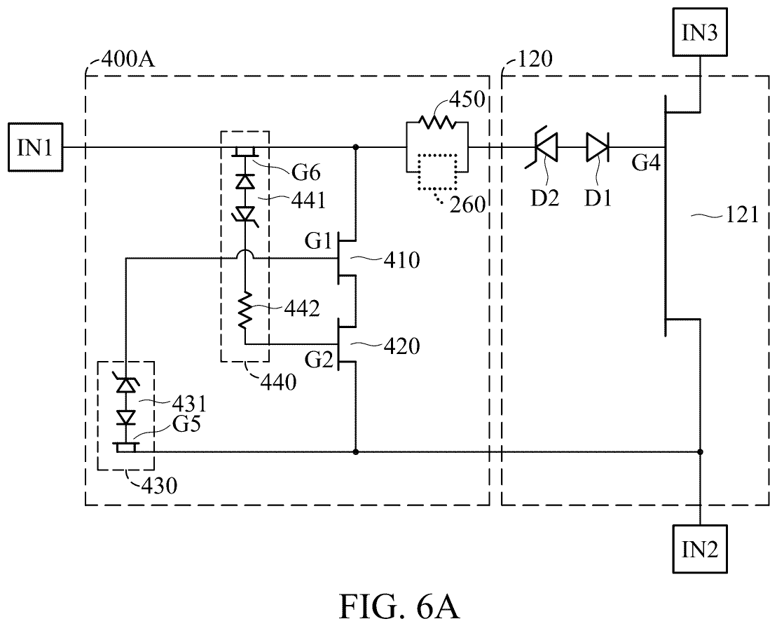

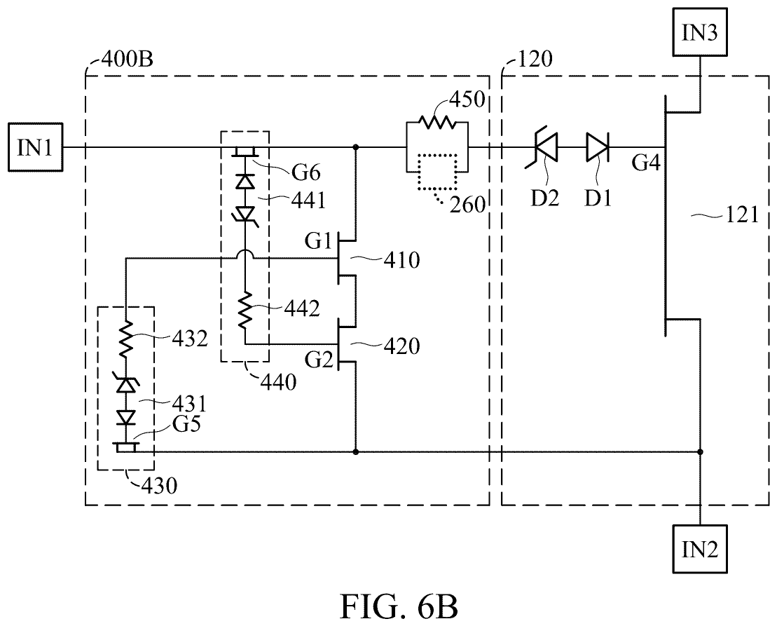

FIG. 6A is a schematic diagram of an electrostatic discharge protection circuit 400A in accordance with some embodiments of the disclosure. In this embodiment, the electrostatic discharge protection circuit 400A includes high electron mobility transistors 410 and 420, current clamping circuits 430 and 440, a resistor 450 and the high electron mobility transistor 260. The high electron mobility transistors 410 and 420 are connected in series between input terminals IN1 and IN2. The resistor 450 and the high electron mobility transistor 260 are connected in parallel between the input terminal IN1 and the core circuit 120. Since the characteristics of the high electron mobility transistors 410 and 420 are similar to the characteristics of the high electron mobility transistors 210 and 220 in FIG. 2, the related description is omitted here. Since the characteristics of the resistor 450 are similar to the characteristics of the resistor 250 in FIG. 2, the related description is omitted here. In addition, the connection, equivalent circuit and characteristics of the high electron mobility transistor 260 can be referred to the foregoing description, and the related description is omitted here.

The current clamping circuit 430 is coupled between the gate G1 of the high electron mobility transistor 410 and the input terminal IN2, and includes a high electron mobility transistor 431. Since the characteristics of the high electron mobility transistor 431 are similar to the characteristics of the high electron mobility transistor 231 in FIG. 4A, the related description is omitted here.

The current clamping circuit 440 is coupled between the input terminal IN1 and the gate G2 of the high electron mobility transistor 420. In this embodiment, the current clamping circuit 440 includes a high electron mobility transistor 441 and a resistor 442. The drain and source of the high electron mobility transistor 441 are coupled to the input terminal IN1. The resistor 442 is coupled between the gate G6 of the high electron mobility transistor 441 and the gate G2 of the high electron mobility transistor 420.

In normal operation (i.e., no electrostatic discharge event occurs), the high electron mobility transistor 441 and the resistor 442 block the current from the input terminal IN1 from entering the gate G2 of the high electron mobility transistor 420. Since the high electron mobility transistor 420 is turned off, no current passes through the high electron mobility transistors 410 and 420.

When the electrostatic discharge event does not occur and the enhancement-mode high electron mobility transistor 121 is turned on, the high electron mobility transistor 260 is turned off. At this time, the gate resistance of the enhancement-mode high electron mobility transistor 121 in ON state is only the equivalent resistance of the resistor 450. For example, when no electrostatic discharge event has occurred and the enhancement-mode high electron mobility transistor 121 is turned off, the high electron mobility transistor 260 is turned on. At this time, the gate resistance of the enhancement-mode high electron mobility transistor 121 is the equivalent resistance of the resistor 450 and the resistor 262 (FIG. 3B) in parallel connection. Therefore, relative to the resistance value of the enhancement-mode high electron mobility transistor 121 in ON state, the enhancement-mode high electron mobility transistor 121 has a smaller resistance value in OFF state.

FIG. 6B is a schematic diagram of an electrostatic discharge protection circuit 400B in accordance with some embodiments of the disclosure. FIG. 6B is similar to FIG. 6A, except that the current clamping circuit 430 includes an additional resistor 432. In this embodiment, the resistor 432 is coupled between the gate G5 of the high electron mobility transistor 431 and the gate G1 of the high electron mobility transistor 410. The resistor 432 is used to reduce the current which enters the high electron mobility transistor 410, this ensures that the high electron mobility transistor 410 is completely turned off when there is no electrostatic discharge event.

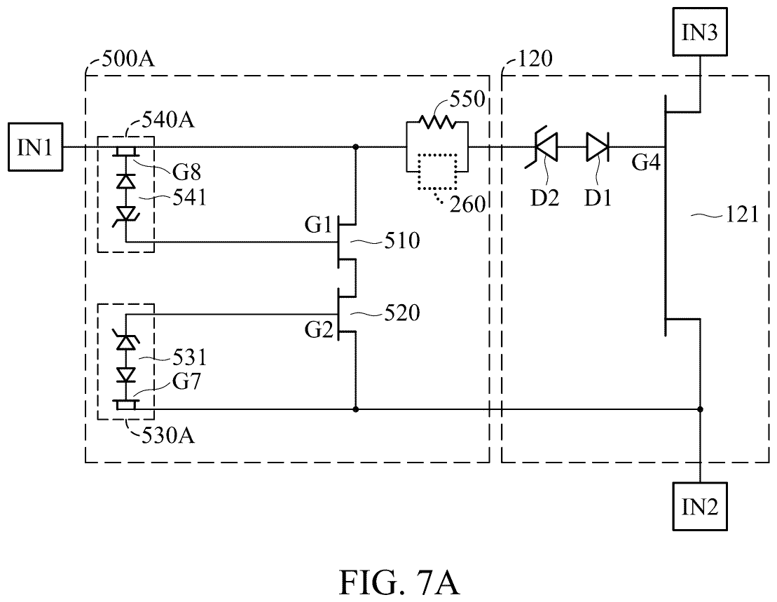

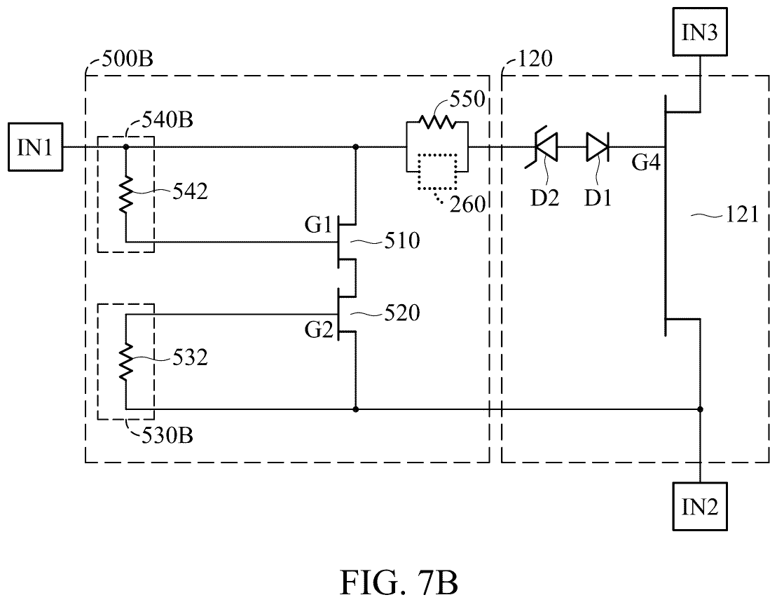

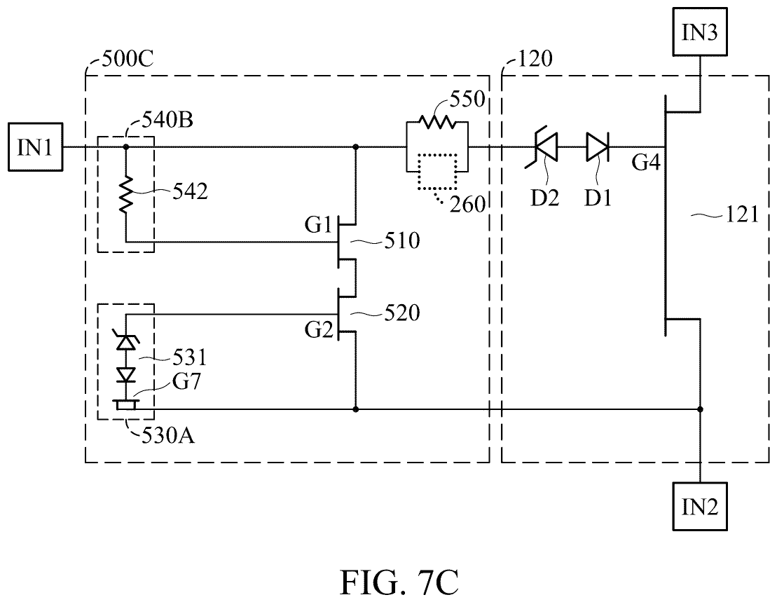

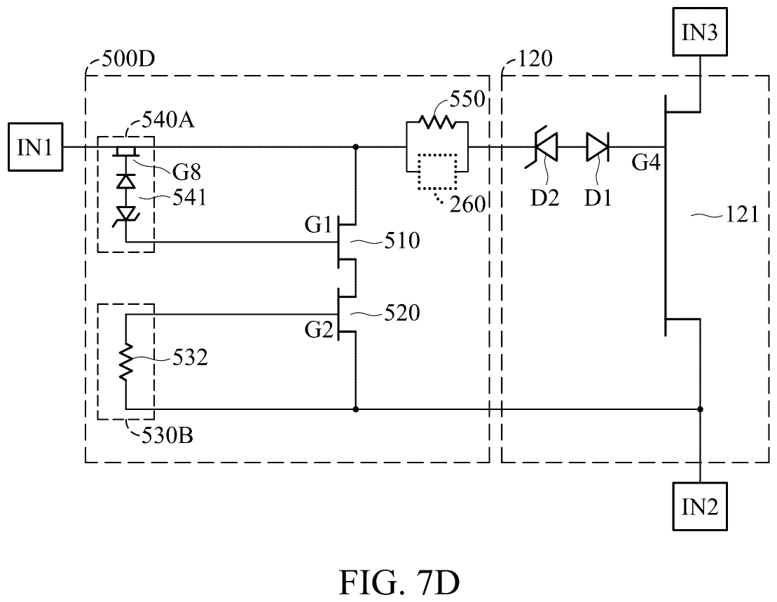

FIG. 7A is a schematic diagram of an electrostatic discharge protection circuit 500A in accordance with some embodiments of the disclosure. As shown in FIG. 7A, the electrostatic discharge protection circuit 500A is coupled between the input terminal IN1 and the core circuit 120 to prevent the electrostatic discharge current from the input terminal IN1 from entering the core circuit 120. In this embodiment, the electrostatic discharge protection circuit 500A includes high electron mobility transistors 510 and 520, current clamping circuits 530A and 540A, a resistor 550 and the high electron mobility transistor 260.

The high electron mobility transistor 510 is coupled to the input terminal IN1. The high electron mobility transistor 520 is coupled between the high electron mobility transistor 510 and the input terminal IN2. The resistor 550 and the high electron mobility transistor 260 are connected in parallel between the input terminal IN1 and the core circuit 120. Since the characteristics of the high electron mobility transistors 510 and 520 and the resistor 550 are similar to the characteristics of the high electron mobility transistors 210 and 220 and the resistor 250 in FIG. 2, the related description is omitted here. In addition, the connection, equivalent circuit and characteristics of the high electron mobility transistor 260 may be referred to the foregoing description, and the related description is omitted here.

When an electrostatic discharge event occurs at the input terminal IN1 and the input terminal IN2 receives a ground voltage, the gate voltage of the high electron mobility transistor 510 is gradually increased due to the coupling effect of the parasitic capacitance between the drain and the gate G1 of the high electron mobility transistor 510. When the gate voltage of the high electron mobility transistor 510 reaches the first target value, the high electron mobility transistor 510 is turned on. Therefore, the drain voltage of the high electron mobility transistor 520 increases. At this time, the gate voltage of the high electron mobility transistor 520 is gradually increased due to the coupling effect of the parasitic capacitance between the drain and the gate G2 of the high electron mobility transistor 520. When the gate voltage of the high electron mobility transistor 520 reaches the second target value, the high electron mobility transistor 520 is turned on. Since the high electron mobility transistors 510 and 520 are turned on, an electrostatic discharge current is released to the input terminal IN2 from the input terminal IN1 and passes through the high electron mobility transistors 510 and 520. No electrostatic discharge current enters the core circuit 120, and this ensures that the core circuit 120 will not be damaged by the electrostatic discharge current.

When an electrostatic discharge event occurs at the input terminal IN3 and the input terminal IN2 receives a ground voltage, the enhancement-mode high electron mobility transistor 121 in the core circuit 120 releases an electrostatic discharge current to the input terminal IN2 from the input terminal IN3. Similarly, when an electrostatic discharge event occurs at the input terminal IN2 and the input terminal IN3 receives the ground voltage, the enhancement-mode high electron mobility transistor 121 releases the electrostatic discharge current to the input terminal IN3 from the input terminal IN2. No electrostatic discharge current enters the gate G4 of the enhancement-mode high electron mobility transistor 121, which helps ensure that the gate G4 of the enhancement-mode high electron mobility transistor 121 will not be damaged by the electrostatic discharge current.

The current clamping circuit 530A is coupled between the input terminal IN2 and the gate G2 of the high electron mobility transistor 520. In this embodiment, the current which enters the gate G2 of the high electron mobility transistor 520 from the input terminal IN2 is limited by the current clamping circuit 530A. When there is no electrostatic discharge event, the current clamping circuit 530A blocks the current from the input terminal IN2 from entering the gate G2 of the high electron mobility transistor 520. Therefore, the high electron mobility transistor 520 is completely turned off to reduce the leakage current of the electrostatic discharge protection circuit 500a.

The structure of the current clamping circuit 530A is not limited in the present disclosure. Any circuit structure may serve as the current clamping circuit 530A, as long as the circuit is capable of blocking current. In this embodiment, the current clamping circuit 530A is a high electron mobility transistor 531. The source and drain of the high electron mobility transistor 531 are coupled to the input terminal IN2. The gate G7 of the high electron mobility transistor 531 is coupled to the gate G2 of the high electron mobility transistor 520. In this embodiment, the high electron mobility transistor 531 includes a back-to-back diode pair to block the current from the input terminal IN2 from entering the gate G2 of the high electron mobility transistor 520.

The current clamping circuit 540A is coupled between the input terminal IN1 and the gate G1 of the high electron mobility transistor 510. In this embodiment, the current flowing from the input terminal IN1 into the gate G1 of the high electron mobility transistor 510 is limited by the current clamping circuit 540A. When there is no electrostatic discharge event, the current clamping circuit 540A blocks the current from the input terminal IN1 from entering the gate G1 of the high electron mobility transistor 510. Therefore, the high electron mobility transistor 510 is completely turned off to reduce the electrostatic discharge protection circuit. 500A leakage current.

The structure of the current clamping circuit 540A is not limited in the present disclosure. Any circuit may serve as the current clamping circuit 540A, as long as the circuit is capable of blocking current. In this embodiment, the current clamping circuit 540A is a high electron mobility transistor 541. The source and drain of the high electron mobility transistor 541 are coupled to the input terminal IN1. The gate G8 of the high electron mobility transistor 541 is coupled to the gate G1 of the high electron mobility transistor 510. In this embodiment, the high electron mobility transistor 541 includes a back-to-back diode pair to block the current from the input terminal IN1 from entering the gate G1 of the high electron mobility transistor 510.

When the electrostatic discharge event does not occur and the enhancement-mode high electron mobility transistor 121 is turned on, the high electron mobility transistor 260 is turned off. At this time, the gate resistance of the enhancement-mode high electron mobility transistor 121 in ON state is only the equivalent resistance of the resistor 550. For example, when no electrostatic discharge event has occurred and the enhancement-mode high electron mobility transistor 121 is turned off, the high electron mobility transistor 260 is turned on. At this time, the gate resistance of the enhancement-mode high electron mobility transistor 121 is the equivalent resistance of the resistor 550 and the resistor 262 (FIG. 3B) in parallel connection. Therefore, relative to the resistance value of the enhancement-mode high electron mobility transistor 121 in ON state, the enhancement-mode high electron mobility transistor 121 has a smaller resistance value in OFF state.

FIG. 7B is a schematic diagram of an electrostatic discharge protection circuit 500B in accordance with some embodiments of the disclosure. The electrostatic discharge protection circuit 500B includes high electron mobility transistors 510 and 520, current clamping circuits 530B and 540B, a resistor 550 and the high electron mobility transistor 260. FIG. 7B is similar to FIG. 7A, except that the structures of the current clamping circuits 530B and 540B in FIG. 7B are different from the structures of the current clamping circuits 530A and 540A in FIG. 7A. In this embodiment, the current clamping circuit 530B includes a resistor 532, and the current clamping circuit 540B includes a resistor 542.

The resistor 532 is directly connected between the input terminal IN2 and the gate G2 of the high electron mobility transistor 520 to reduce the current that enters the gate G2 of the high electron mobility transistor 520 from the input terminal IN2. The resistor 542 is directly connected between the input terminal IN1 and the gate G1 of the high electron mobility transistor 510 to reduce the current that enters the gate G1 of the high electron mobility transistor 510 from the input terminal IN1 into. Since the current which enters the gate G1 of the high electron mobility transistor 510 and the gate G2 of the high electron mobility transistor 520 is limited by the resistor 542 and the resistor 532, this ensures that the high electron mobility transistors 510 and 520 are turned off in the absence of an electrostatic discharge event.

FIG. 7C is a schematic diagram of an electrostatic discharge protection circuit 500C in accordance with some embodiments of the disclosure. The electrostatic discharge protection circuit 500C includes the high electron mobility transistors 510 and 520, the current clamping circuits 530A and 540B, the resistor 550 and the high electron mobility transistor 260. Since the high electron mobility transistors 510 and 520, the current clamping circuits 530A and 540B, the resistor 550 and the high electron mobility transistor 260 have been described above, the related description is omitted here. Since the current flowing into the gate G1 of the high electron mobility transistor 510 and the gate G2 of the high electron mobility transistor 520 is limited by the current clamping circuit 540B and the current clamping circuit 530A, this ensures that the high electron mobility transistors 510 and 520 are turned off in the absence of an electrostatic discharge event.

FIG. 7D is a schematic diagram of an electrostatic discharge protection circuit 500D in accordance with some embodiments of the disclosure. The electrostatic discharge protection circuit 500D includes the high electron mobility transistors 510 and 520, the current clamping circuits 530B and 540A, the resistor 550 and the high electron mobility transistor 260. Since the high electron mobility transistors 510 and 520, the current clamping circuits 530B and 540A, the resistor 550 and the high electron mobility transistor 260 have been described above, the related description is omitted here. Since the current flowing into the gate G1 of the high electron mobility transistor 510 and the gate G2 of the high electron mobility transistor 520 is limited by the clamping circuit 540A and the current clamping circuit 530B, this ensures that the high electron mobility transistors 510 and 520 are turned off in the absence of an electrostatic discharge event.

The embodiment of the present disclosure provides an electrostatic discharge protection circuit for protecting a core circuits in an operating system. The electrostatic discharge protection circuit includes a first high electron mobility transistor, a second high electron mobility transistor, a first resistor and a third high electron mobility transistor. The first high electron mobility transistor is coupled to the first input terminal. The second high electron mobility transistor is coupled between the first high electron mobility transistor and the second input terminal. The first resistor is coupled between the first input terminal and the core circuit. The third high electron mobility transistor is connected in parallel with the first resistor. The third gate of the third high electron mobility transistor is coupled to the first electrode of the third high electron mobility transistor.

In some embodiments, the third gate and a first electrode of the third high electron mobility transistor are coupled to the first input terminal. A second electrode of the third high electron mobility transistor is coupled to the core circuit. In some embodiments of the present invention, the first electrode may be the source or drain of the third high electron mobility transistor. When the gate of the third high electron mobility transistor is directly connected to the source or drain. The third high electron mobility transistor having this connection can also be called a diode-connected transistor, and its equivalent circuit may serve as a diode and a resistor connected in series. Two ends of the resistor are respectively coupled to the first input terminal and the cathode of the diode. Furthermore, the anode of the diode is coupled to the core circuit.

In some embodiments, the core circuit includes an enhancement-mode high electron mobility transistor coupled to the second input terminal and the third input terminal. The enhancement-mode high electron mobility transistor, the third high electron mobility transistor and the first resistor are connected in parallel between the first input terminal and the fourth gate of the enhancement-mode high electron mobility transistor. The anode of the equivalent diode of the third high electron mobility transistor is coupled to the fourth gate of the enhancement-mode high electron mobility transistor.

The electrostatic discharge protection circuit of the embodiment of the present disclosure may respectively discharge electrostatic charges away from the core circuit when electrostatic discharge events occurs at any two of the first to third input terminals.

For example, when an electrostatic discharge event occurs at the first input terminal or the second input terminal, the first high electron mobility transistor and the second high electron mobility transistor are turned on to prevent electrostatic discharge current form entering the core circuit.

Moreover, when an electrostatic discharge event occurs at the first input terminal and the second input terminal receives a ground voltage, the third high electron mobility transistor is turned off. At this time, the voltage of the fourth gate of the enhancement-mode high electron mobility transistor the will be clamped (limited) to a predetermined value by the first resistor to prevent the electrostatic discharge current from entering the enhancement-mode high electron mobility transistor. Therefore, the enhancement-mode high electron mobility transistor will not be damaged by the electrostatic discharge current.

In some embodiments, since the core circuit including the enhancement-mode high electron mobility transistor also has the capability of releasing electrostatic discharge current, the electrostatic discharge current from the second input terminal or the third input terminal may be prevented from entering the fourth gate of the enhancement-mode high electron mobility transistor and another core circuit connected in parallel with the enhancement-mode high electron mobility transistor. Therefore, the enhancement-mode high electron mobility transistor may be integrated into the electrostatic discharge protection circuit. For example, when an electrostatic discharge event occurs at the third input terminal and the second input terminal receives a ground voltage, the electrostatic discharge current is released to the second input terminal from the third input terminal by the enhancement-mode high electron mobility transistor. Similarly, when an electrostatic discharge event occurs at the second input terminal and the third input terminal receives a ground voltage, the electrostatic discharge current is released to the third input terminal from the second input terminal by the enhancement-mode high electron mobility transistor.

In some embodiments, the electrostatic discharge protection circuit further includes a first current clamping circuit and a second current clamping circuit.

In some embodiments, the first current clamping circuit is coupled between the first gate of the first high electron mobility transistor and the second input terminal. The second current clamping circuit is coupled between the second gate of the second high electron mobility transistor and the first input terminal. In this embodiment, the first current clamping circuit includes a second resistor, a fifth high electron mobility transistor, or a combination thereof. The second current clamping circuit includes a third resistor, a sixth high electron mobility transistor, or a combination thereof.

In some embodiments, the first current clamping circuit is coupled between the second input terminal and the second gate of the second high electron mobility transistor. The second current clamping circuit is coupled between the first input terminal and the first gate of the first high electron mobility transistor. In this embodiment, the first current clamping circuit includes a fourth resistor, a seventh high electron mobility transistor, or a combination thereof. The second current clamping circuit includes a fifth resistor, an eighth high electron mobility transistor, or a combination thereof.

In some embodiments, the electrostatic discharge capability of the whole circuit may be improved by increasing the current conduction capability from the second input terminal to the third input terminal of the electrostatic discharge circuit, for example, increasing the area.

When the core circuit in the operating system is in normal operation (i.e., no electrostatic discharge event occurs), the electrostatic discharge circuit operates in normal mode. In normal mode, the first high electron mobility transistor or the second high electron mobility transistor is turned off to reduce leakage current. Furthermore, through the first resistor and the third high electron mobility transistor connected in parallel between the first input terminal and the fourth gate electrode (the core circuit) of the high electron mobility transistor, the enhancement-mode high electron mobility transistor of the core circuit may be connected to the gate resistors with different resistance values in ON or OFF state. Therefore, the operating system may have optimized performance of both fast switching speed and electromagnetic interference (EMI) elimination. Moreover, the first resistor and third high electron mobility transistor may be formed by using III-V semiconductor processes, and may be integrated with other current clamping circuits and core circuits of the electrostatic discharge protection circuit of the operating system to form on the substrate. No additional discrete passive component including the first resistor and the third high electron mobility transistor is required to be disposed external to the substrate.

For example, when the electrostatic discharge event does not occur and the enhancement-mode high electron mobility transistor is turned on, the third high electron mobility transistor is turned off. The gate resistance of the enhancement-mode high electron mobility transistor is only the resistance of the first resistor. When no electrostatic discharge event has occurred and the enhancement-mode high electron mobility transistor is turned off, the third high electron mobility transistor is turned on. The resistance value of the enhancement-mode high electron mobility transistor in OFF state is the equivalent resistance of the resistor and the diode-connected third high electron mobility transistor in parallel connection. Therefore, compared with the resistance of the enhancement-mode high electron mobility transistor in ON state, the enhancement-mode high electron mobility transistor has a smaller resistance value in OFF state. The turn-off speed of the enhancement-mode high electron mobility transistor is improved.

It will be understood that when an element is referred to as being “coupled to” another element, it can be directly coupled to the other element or intervening elements may be present. In contrast, when an element is referred to as be “directly connected to” another element, there are no intervening elements present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge protection circuit for protecting a core circuit, comprising:
a first high electron mobility transistor coupled to a first input terminal;
a second high electron mobility transistor coupled between the first high electron mobility transistor and a second input terminal;
a first resistor coupled between the first input terminal and the core circuit; and
a third high electron mobility transistor connected in parallel with the first resistor, wherein a third gate of the third high electron mobility transistor is coupled to a first electrode of the third high electron mobility transistor.

2. The electrostatic discharge protection circuit as claimed in claim 1, wherein the third gate and the first electrode of the third high electron mobility transistor are coupled to the first input terminal, and a second electrode of the third high electron mobility transistor is coupled to the core circuit.

3. The electrostatic discharge protection circuit as claimed in claim 2, wherein the first electrode is a third source of the third high electron mobility transistor, and the second electrode is a third drain of the third high electron mobility transistor.

4. The electrostatic discharge protection circuit as claimed in claim 2, wherein the first electrode is a third drain of the third high electron mobility transistor, and the second electrode is a third source of the third high electron mobility transistor.

5. The electrostatic discharge protection circuit as claimed in claim 1, wherein the core circuit comprises:
an enhancement-mode high electron mobility transistor, wherein the enhancement-mode high electron mobility transistor is coupled to the second input terminal and a third input terminal.

6. The electrostatic discharge protection circuit as claimed in claim 5, wherein the third high electron mobility transistor and the first resistor are connected in parallel between the first input terminal and a fourth gate of the enhancement-mode high electron mobility transistor.

7. The electrostatic discharge protection circuit as claimed in claim 6, wherein when no electrostatic discharge event has occurred and the enhancement-mode high electron mobility transistor is turned on, the third high electron mobility transistor is turned off.

8. The electrostatic discharge protection circuit as claimed in claim 6, wherein when no electrostatic discharge event has occurred and the enhancement-mode high electron mobility transistor is turned off, the third high electron mobility transistor is turned on.

9. The electrostatic discharge protection circuit as claimed in claim 1, wherein when an electrostatic discharge event occurs at the first input terminal or the second input terminal, the first high electron mobility transistor and the second high electron mobility transistors are turned on to prevent an electrostatic discharge current from entering the core circuit.

10. The electrostatic discharge protection circuit as claimed in claim 1, further comprising:
an enhancement-mode high electron mobility transistor connected in parallel to the core circuit, wherein the enhancement-mode high electron mobility transistor is coupled to the second input terminal and a third input terminal, wherein the third high electron mobility transistor and the first resistor are connected in parallel between the first input terminal and a fourth gate of the enhancement-mode high electron mobility transistor;
wherein when an electrostatic discharge event occurs at the first input terminal and the second input terminal receives a ground voltage, the first and second high electron mobility transistors are turned on to prevent an electrostatic current from the first input terminal from entering into the enhancement-mode high electron mobility transistor,
when the electrostatic discharge event occurs at the third input terminal and the second input terminal receives the ground voltage, the enhancement-mode high electron mobility transistor releases the electrostatic discharge current from the third input terminal to the second input terminal, and
when the electrostatic discharge event occurs at the second input terminal and the third input terminal receives the ground voltage, the enhancement-mode high electron mobility transistor releases the electrostatic discharge current from the second input terminal to the third input terminal.

11. The electrostatic discharge protection circuit as claimed in claim 1, further comprising:
a first current clamping circuit coupled between a first gate of the first high electron mobility transistor and the second input terminal; and
a second current clamping circuit coupled between a second gate of the second high electron mobility transistor and the first input terminal.

12. The electrostatic discharge protection circuit as claimed in claim 11, wherein the first current clamping circuit further comprises:
a second resistor directly connected between the first gate of the first high electron mobility transistor and the second input terminal, and
the second current clamping circuit further comprises:
a third resistor directly connected between the second gate of the second high electron mobility transistor and the first input terminal.

13. The electrostatic discharge protection circuit as claimed in claim 11, wherein the first current clamping circuit comprises:
a fifth high electron mobility transistor, wherein a fifth drain and a fifth source of the fifth high electron mobility transistor are coupled to the second input terminal, and a fifth gate of the fifth high electron mobility transistor is coupled to the first gate of the first high electron mobility transistor.

14. The electrostatic discharge protection circuit as claimed in claim 13, wherein the first current clamping circuit further comprises:
a second resistor coupled between the fifth gate of the fifth high electron mobility transistor and the first gate of the first high electron mobility transistor.

15. The electrostatic discharge protection circuit as claimed in claim 13, wherein the second current clamping circuit comprises:
a sixth high electron mobility transistor, wherein a sixth drain and a sixth source of the sixth high electron mobility transistor are coupled to the first input terminal, and a sixth gate of the sixth high electron mobility transistor is coupled to the second gate of the second high electron mobility transistor.

16. The electrostatic discharge protection circuit as claimed in claim 15, wherein the second current clamping circuit further comprises:
a third resistor coupled between the sixth gate of the sixth high electron mobility transistor and the second gate of the second high electron mobility transistor.

17. The electrostatic discharge protection circuit as claimed in claim 11, wherein when an electrostatic discharge event occurs at the first input terminal or the second input terminal, the first high electron mobility transistor and the second high electron mobility transistor are turned on to prevent an electrostatic discharge current from entering the core circuit.

18. The electrostatic discharge protection circuit as claimed in claim 1, further comprising:
a first current clamping circuit coupled between a second gate of the second high electron mobility transistor and the second input terminal; and
a second current clamping circuit coupled between a first gate of the first high electron mobility transistor and the first input terminal.

19. The electrostatic discharge protection circuit as claimed in claim 18, wherein the first current clamping circuit comprises:
a seventh high electron mobility transistor, wherein a seventh drain and a seventh source of the seventh high electron mobility transistor are coupled to the second input terminal, and a seventh gate of the seventh high electron mobility transistor is coupled to the second gate of the second high electron mobility transistor.

20. The electrostatic discharge protection circuit as claimed in claim 18, wherein the second current clamping circuit comprises:
an eighth high electron mobility transistor, wherein an eighth drain and an eighth source of the eighth high electron mobility transistor are coupled to the first input terminal, and an eighth gate of the eighth high electron mobility transistor is coupled to the first gate of the first high electron mobility transistor.

21. The electrostatic discharge protection circuit as claimed in claim 18, wherein the second current clamping circuit comprises:
a fourth resistor directly connected to the first input terminal and the first gate of the first high electron mobility transistor.

22. The electrostatic discharge protection circuit as claimed in claim 18, wherein the first current clamping circuit comprises:
a fifth resistor directly connected to the second input terminal and the second gate of the second high electron mobility transistor.
